(19) United States
(12) Patent Application Publication
(10) Pub. No.: US 2005/0282311 A1
(43) Pub. Date: Dec. 22, 2005

(54) FLIP-CHIP SUBSTRATE AND FLIP-CHIP BONDING PROCESS THEREOF

(76) Inventors: Yu-Wen Chen, Kaohsiung (TW); Ming-Lun Ho, Kaohsiung (TW); Chun-Yang Lee, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/908,336

(22) Filed: May 9, 2005

Related U.S. Application Data
(63) Continuation of application No. 10/605,215, filed on Sep. 16, 2003, now abandoned.

(30) Foreign Application Priority Data
Dec. 18, 2002 (TW) 91136481

(51) Int. Cl. H01L 21/60

(52) U.S. Cl. 438/108; 438/615

(57) ABSTRACT

A flip-chip substrate for bonding with a chip is provided. The chip has an active surface with a plurality of bonding pads and each bonding pad has a bump thereon. The flip-chip substrate has a plurality of contact pads that correspond in positions with the bonding pads on the chip such that the chip pads are aligned to their corresponding contact pads at the melting point of the bump material.

### CROSS-REFERENCE TO RELATED APPLICATION

This application is a continuation of a prior application Ser. No. 10/605,215, filed Sep. 16, 2003, which claims the priority benefit of Taiwan application serial no. 91136481, filed Dec. 18, 2002.

### BACKGROUND OF THE INVENTION

1. Field of Invention

The present invention relates to a flip-chip substrate. More particularly, the present invention relates to a flip-chip substrate and a flip-chip bonding process thereof having the capacity to improve bonding reliability between the chip and the substrate.

2. Description of Related Art

In the manufacturing of semiconductors, integrated circuits (IC) can be roughly divided into three major fabrication stages, namely, fabrication of a raw die, fabrication of IC on the die to form an IC chip and packaging the IC chip inside a package. The raw die fabrication stage includes fabricating silicon wafer. The IC fabrication stage includes designing circuits, producing various masks to form all required circuits and dicing up the wafer into IC chips. Each IC chip diced out from the wafer is then electrically connected to external devices via contact pads on the chip. Thereafter, the chip is enclosed inside a plastic package. The package protects the chip against moisture, heat and the interference by external signals. In addition, the package also provides an interface for connecting the chip with other circuits.

As the level of integration continues to increase, a number of associated packaging structures are developed for the chips. Flip-chip technique is one of the packaging methods that can reduce overall chip package area and average signal transmission path. At present, flip-chip technique is applied to many types of packaging modules including chip scale package (CSP), direct chip attach (DCA) package and multi-chip module (MCM).

In a conventional flip-chip bonding process, a plurality of bumps is formed over the respective contact pads on the chip and a screen-printing method is conducted to deposit some solder material over each contact pad on the substrate. Thereafter, the chip is flipped over such that the bumps on the chip are aligned with the solder material over various contact pads. A reflow process is executed so that the solder material and the bump are melted together to form a plurality of junction blocks. Through the junctions blocks formed by bonding the bumps and the solder material, the chip and the substrate are electrically connected.

In a conventional flip-chip bonding process, the distance of separation of the contact pads on the substrate is designed according to the distance of separation of the bumps on the chip. However, the coefficient of thermal expansion between a chip and a substrate is usually large. Hence, in the process of attaching a chip with a large surface area onto a substrate, bumps near the outer edge of the chip can hardly align with a corresponding contact pad on the substrate to form a good bond. In other words, the bumps may peel off from the substrate at times due to structural nonconformity. Consequently, reliability of electrical connection between the chip and the substrate is poor.

### SUMMARY OF THE INVENTION

Accordingly, one object of the present invention is to provide a flip-chip substrate and a flip-chip bonding process thereof such that contact pads (cavities) on the substrate are able to align properly with corresponding bonding pads (bumps) on the chip at the melting point of the bump. Ultimately, a good bondage is formed between the chip and the substrate so that the yield rate of reliability testing is improved.

To achieve these and other advantages and in accordance with the purpose of the invention, as embodied and broadly described herein, the invention provides a flip-chip substrate for bonding with a chip. The chip has an active surface with a plurality of bonding pads thereon. Furthermore, each bonding pad has a bump thereon. The flip-chip substrate has a plurality of contact pads thereon with each contact pad corresponds to one of the bonding pads. At the melting point of the bumps, the bonding pads are aligned with their respective contact pads.

This invention also provides a flip-chip bonding process for joining a chip and a substrate together. The chip has an active surface with a plurality of bonding pads thereon. Furthermore, each bonding pad has a bump thereon. One of the bonding pads (one of the bumps) serves as a first expansion reference mark. The substrate has a contact pad (cavity) that corresponds to the bonding pad (bump). Another contact pad (cavity) that corresponds to the first expansion reference mark serves as a second expansion reference mark. The flip-chip bonding process includes aligning the first expansion reference mark on the chip with the second expansion reference mark on the substrate when the chip is placed over the substrate. Thereafter, a reflow process is executed to join the bumps with their respective cavities. When the substrate and the chip reaches a preset temperature such as the melting point of the bumps in the reflow process, all the cavities (contact pads) are aligned with their corresponding bumps (bonding pads).

This invention also provides a chip for bonding to a substrate. The substrate has a plurality of cavities. The chip has a plurality of bonding pads that correspond to the cavities in the substrate. The bonding pads are located on the active surface of the chip. Furthermore, each bonding pad has a bump thereon. When the chip and the substrate is heated to a preset temperature such as the melting point of the bumps, all the bumps are aligned with their corresponding cavities on the substrate.

The flip-chip substrate according to this invention makes due consideration regarding the difference in coefficient of thermal expansion between the substrate and the chip. The distance between the cavities (the contact pads) at room temperature is purposely set to a value smaller than the distance between corresponding bumps (bonding pads) on the chip. When the chip and the substrate are heated to the melting point of the bumps in a reflow process, all the cavities on the substrate are properly aligned with the bumps on the chip. Therefore, the substrate and the chip are able to form a good bondage and prevent the bumps from breaking away. In other words, reliability of the bondage between the chip and the substrate is greatly improved.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1 to 4 are schematic cross-sectional views showing the steps for fabricating a flip-chip package according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

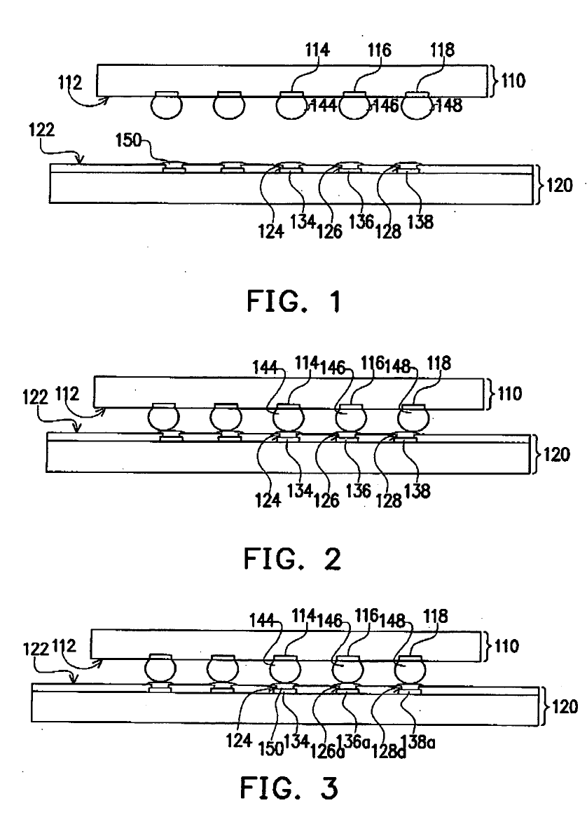

FIGS. 1 to 4 are schematic cross-sectional views showing the steps for fabricating a flip-chip package according to one preferred embodiment of this invention. In particular, FIG. 1 is a cross sectional view showing a flip-chip substrate and a chip at room temperature. As shown in FIG. 1, a chip 100 having an active surface 112 with a plurality of bonding pads such as 114, 116 and 118 thereon is provided. Furthermore, each bonding pad (114, 116, 118) has a corresponding bump (144, 146, 148). In this embodiment of the invention, the bonding pads 114, 116, 118 and their corresponding bumps 144, 146, 148 are arranged into an array format, for example. The bonding pad 114 (bump 144) located at the center of the distribution region serves as an expansion reference mark in a subsequent reflow process.

As shown in FIG. 1, a substrate 120 having a substrate surface 122 for attaching the chip 110 is provided. The substrate surface 122 has a plurality of cavities 124, 126, 128 thereon. Furthermore, the substrate surface 122 has a plurality of embedded contact pads 134, 136, 138 exposed by the respective cavities 124, 126 and 128. Preferably, some solder material 150 such as solder paste is deposited into the cavities 124, 126, 128 on the substrate 120. Similarly, the cavities 124, 126 and 128 and the corresponding contact pads 134, 136, 138 are arranged into an array format. The contact pad 134 (cavity 124) located at the center of the distribution region serves as an expansion reference mark in a subsequent reflow process. With this setup, other bonding pads such as 116 and 118 are misaligned with their corresponding contact pads 136 and 138, when the contact pad 134 is aligned with the bonding pad 114 on the chip 110 at room temperature. That is, other bumps such as 146 and 148 are misaligned with their corresponding cavities 126 and 128 when the cavity 124 is aligned with the bump 144 on the chip 110 at room temperature.

In this embodiment, the distance separating two neighboring cavities is purposely set to have a value smaller than the distance separating the two corresponding bumps at room temperature. This is because the substrate 120 generally has a coefficient of thermal expansion greater than the chip 100. As the chip and the substrate 120 are heated to a high temperature such as the melting point of the bump material, the contact pads 134, 136, 138 (cavities 124, 126, 128) on the substrate 120 having a higher thermal expansion moves relative to their corresponding bonding pads 114, 116, 118 (bumps 144, 146, 148) on the chip 110. Consequently, all bumps and corresponding cavities are aligned at the bump melting point.

In FIG. 2, the chip 110 is flipped over so that the bonding pad 114 on the chip 110 is aligned with the cavity hole 124 on the substrate 120. Hence, the bumps 114, 116, 118 on the chip 110 are in contact with the solder material inside the respective cavities 124, 126, 128 on the substrate 120. The substrate 120 and the chip 110 are transferred into a reflow over to carry out a reflow process. Due to the difference in coefficients of thermal expansion between the chip 110 and the substrate 120, distance separating any cavities are set to a value smaller than distance separating corresponding bumps. Furthermore, deviation in alignment between cavities in the outer perimeter such as the cavity 128 and the corresponding bump 118 is greater than deviation in alignment between cavities in the inner perimeter such as the cavity 126 and the corresponding bump 116. In other words, aside from the alignment between the expansion reference bump 144 (the bonding pad 114) and the cavity 124 (the contact pad 134), other bumps and cavities have variable degree of misalignment. When the chip 110 is positioned over the substrate 120, the outermost bumps 118 and cavities 128 are in partial contact. Hence, conventional bonding process can be used to join the chip 110 and the substrate 120 designed according to this invention.

FIG. 3 shows the heated chip 110 and the substrate 120 in a reflow process. Since the substrate 120 has a coefficient of thermal expansion substantially larger than the chip 110, overall expansion of the chip 110 can be ignored. Due to thermal expansion, the cavity 126 (contact pad 136) and the cavity 128 (contact pad 138) expand to new locations when the bumps 144, 146, 148 reach the melting point. The new locations are indicated in FIG. 3 by the cavity 126a (contact pad 136a) and the cavity 128a (contact pad 138a). Hence the cavity 126a aligns with the bump 146 while the cavity 128a aligns with the bump 148. In other words, all the bonding pads (bumps) on the chip 110 align with corresponding contact pads (cavities) on the substrate 120.

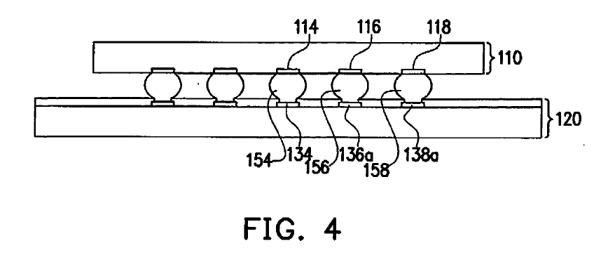

At the melting point of the bump, the bump 144 bonds with the solder material 150 inside the cavity hole 124 on the substrate 120 to form a junction block 154, as shown in FIG. 4. Similarly, the bump 146 bonds with the solder material 150 inside the cavity hole 126a on the substrate 120 to form a junction block 156 and the bump 148 bonds with the solder material 150 inside the cavity hole 128a on the substrate 120 to form a junction block 158. The aforementioned bumps 144, 146, 148 and the cavities 124, 126a, 128a are aligned perfectly before bonding. Hence, all junction blocks have an ideal bond configuration indicated by the flip-chip package in FIG. 4.

The flip-chip substrate 120 according to this invention is designed such that the bumps 144, 146, 148 on the chip 110 align with their respective cavities 124, 126a, 128a when the chip 110 and the substrate 120 are heated to the melting point of the bumps. Thus, the increase misalignment between the bonding pad and substrate contact further out in the perimeter due to difference in coefficients of thermal expansion between the substrate 120 and the chip 110 is compensated for and junction reliability between the chip 110 and the substrate 120 is improved.

In the aforementioned embodiment, a flip-chip substrate having cavities (contact pads) thereon that align with bumps (bonding pads) at the melting point of the bump is disclosed. However, this invention equivalent to the disclosure of a type of chip having bumps (bonding pads) thereon that align with corresponding cavities (contact pads) on a flip-chip substrate at the melting point of the bump.

Moreover, in the aforementioned embodiment, only thermal expansion of the flip-chip substrate 120 is considered. The effect of thermal expansion in the chip 110 is ignored. However, thermal expansion of both the chip 110 and the flip-chip substrate 120 may be considered. After careful analysis of the degree of expansion of both the flip-chip substrate 120 and the chip 110 at the melting point of the bump material, all the cavities on the substrate 120 and corresponding bumps on the chip 110 can be made to align perfectly.

Furthermore, the aforementioned embodiment discloses bonding pads (bumps) and contact pads (cavities) arranged in an array format. However, there are no limitations on the actual configuration of the bumps and cavities. As long as bumps (bonding pads) on the chip 110 and the cavities (contact pads) on the substrate 120 are aligned at the melting point of the bump material, the bonding pads (bumps) and the contact pads (cavities) can be positioned in whatever configurations.

In the aforementioned embodiment, all the cavities on the 120 and corresponding bumps on the chips 110 are aligned at the melting point of the bumps. Yet, perfect alignment need not occur at the melting point. As long as a good junction block configuration is created after bonding the bumps and the cavities, the temperature at which alignment between the cavities and the bumps occurs may differ from the melting point.

In addition, the aforementioned embodiment is used to form a tight bond between bumps and cavities within a structure having a chip carrier and a substrate carrier at the bump melting point. However, this invention can also be used to form a tight bond between bumps and holes within a structure having two chip carriers or a structure having two substrate carriers.

In summary, this invention has at least the following advantages:
1. The flip-chip substrate is designed to compensate for the difference in coefficient of thermal expansion between the chip and the substrate so that the cavities (contact pads) and the bumps (bonding pads) on the chip are always aligned at the melting point of the bumps.
2. Because the chip and the substrate are always aligned at the bonding state, the flip-chip package is able to reproduce an ideal bonding configuration. Hence, overall yield in a reliability test such as temperature cycle test is improved and breakage of the bumps due to poor connection is prevented.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A flip-chip bonding process for a chip bonding to a substrate, wherein the chip has an active surface with a plurality of bumps thereon and the substrate has a plurality of contact pads corresponding to the bumps, the flip-chip bonding process:
aligning the chip with the substrate at a first temperature, wherein the bumps on the chip are not completely aligned to the corresponding contact pads on the substrate; and
performing a reflow process by increasing the first temperature to a second temperature, so that the bumps on the chip are melt and bonded to the corresponding contacts pads on the substrate, wherein the bumps are completely aligned to the corresponding contact pads when the second temperature reaches a melting point of bump.

2. The flip-chip bonding process of claim 1, wherein a space between the bumps is greater than a space between the corresponding contact pads at the first temperature.

3. The flip-chip bonding process of claim 1, wherein the first temperature is a room temperature.

4. The flip-chip bonding process of claim 1, in the step of performing the reflow process, wherein the substrate has a coefficient of thermal expansion greater than that of the chip so that the contact pads on the substrate are aligned to the bumps on the chip.

5. The flip-chip bonding process of claim 1, in the step aligning the chip with the substrate at the first temperature, wherein only one of the bumps is aligned to a corresponding one of the contact pads.

6. The flip-chip bonding process of claim 5, wherein the one of the bumps is any one of the bumps without specific selection.

7. A flip-chip bonding process for a chip bonding to a substrate, wherein the chip has an active surface with a plurality of bumps thereon and the substrate has a plurality of contact pads corresponding to the bumps, the flip-chip bonding process:
setting a space between the bumps on the chip, according to a coefficient of thermal expansion of the chip;
setting a space between the contact pads on the substrate, according to a coefficient of thermal expansion of the substrate;
aligning the chip with the substrate at a first temperature, wherein the bumps on the chip are not completely aligned to the corresponding contact pads on the substrate;
increasing the first temperature to a second temperature in a reflow process, so that the bumps on the chip are melt and bonded to the corresponding contacts pads on the substrate,
wherein the space between the bumps and the space between the contact pads are set according to a relation between the coefficients of thermal expansion of the chip and the substrate, so that the bumps are completely aligned to the corresponding contact pads when the second temperature reaches a melting point of bump.

8. The flip-chip bonding process of claim 7, wherein the space between the bumps in one direction is greater than the space between the corresponding contact pads at the first temperature.

9. The flip-chip bonding process of claim 7, wherein the first temperature is a room temperature.

10. The flip-chip bonding process of claim 7, wherein the coefficient of thermal expansion of the substrate is greater than the coefficient of thermal expansion of the chip.

11. The flip-chip bonding process of claim 7, wherein the space between the bumps and the space between the contact pads are a one-dimensional relation.

12. The flip-chip bonding process of claim 7, in the step aligning the chip with the substrate at the first temperature, wherein only one of the bumps is aligned to a corresponding one of the contact pads.

13. The flip-chip bonding process of claim 12, wherein the one of the bumps is any one of the bumps without specific selection.
